(19) United States
(12) Patent Application Publication
(10) Pub. No.: US 2026/0141151 A1
(43) Pub. Date: May 21, 2026

(54) system and method for modeling characteristics of a transistor

(71) Applicant: Fast SiC Semiconductor Incorporated, Hsinchu (TW)

(72) Inventors: Ting-Fu CHANG, Hsinchu (TW); Fu-Jen HSU, Hsinchu (TW); Cheng-Tyng YEN, Hsinchu (TW)

(21) Appl. No.: 18/950,863

(22) Filed: Nov. 18, 2024

(51) Int. Cl. G06F 30/39; H01L 29/78

(52) U.S. Cl. CPC G06F 30/39; H10D 30/65; H10D 30/668

(57) ABSTRACT

A system and method for modeling characteristics of a transistor uses the following equation to perform a fitting of a set of I-V values of the transistor:

$$y = [ {\prod }_{k = 1}^{n} tanh ( {a}_{k} \times {x}_{1} + {b}_{k} ) ] \times F + c$$

y is a current through the transistor, x₁ is an applied voltage of the transistor, aₖ, bₖ and c are circuit-dependent coefficients, and F is a function related to the applied voltage.

### FIELD OF THE INVENTION

The present invention relates to a method and system for accurately modelling a current-voltage characteristic of a transistor.

### BACKGROUND OF THE INVENTION

With the increasing adoption of wide-bandgap power devices, numerous simulation models have been developed to better align these devices with their real-world performance. The key distinction between SiC and silicon-based devices arises from the unique properties of wide-bandgap semiconductors and the differences in material parameters.

Various approaches to simulation models have been proposed, including parameter extraction techniques specific to SiC device models, SPICE model simulations, static and dynamic models, and models derived from datasheet parameters. Other studies such as temperature characteristics, C-V modeling and the accuracy of dynamic models have also been proposed. More recently, a model incorporating dynamic QGD was introduced, providing a more precise way to model dynamic behavior.

Studies have been conducted on the modulation of third quadrant I-V characteristics for SiC devices, for example, provided in A. U. Rashid, et al., “Datasheet-Driven Compact Model of Silicon Carbide Power MOSFET Including Third-Quadrant Behavior,” IEEE Trans. Power Electron., vol. 36, no. 10, pp. 11748-11762, October 2021, and L. Yan, et al., “A Compact Model Extending the BSIM3 Model for Silicon Carbide Power MOSFETs,” IEEE Trans. Power Electron., vol. 38, no. 4, pp. 4613-4622, April 2023, which are hereby incorporated by reference in its entirety.

While this model has notably enhanced the accuracy of SiC MOSFET performance in the third quadrant and improved the understanding of third quadrant behavior, challenges still exist. In particular, within the practical operating range where V_{GS} is below −4V, the modified-BSIM3 model falls short in accurately predicting the device's electrical characteristics. Therefore, further refinement of the third quadrant I-V model for SiC MOSFETs is essential to improve its accuracy and practical usefulness. This underscores the continued need for research to advance the precision and applicability of these models.

### SUMMARY OF THE INVENTION

According to one aspect of the present disclosure, a system for modeling characteristics of a transistor is provided. The system comprises a circuit and a target transistor. The circuit includes a first capacitor, a second capacitor, a third capacitor, a first current source, a second current source and a body diode. The second capacitor is connected to the first capacitor in series, wherein a gate supply terminal is provided between the first capacitor and the second capacitor. The third capacitor is connected to the first capacitor and the second capacitor in parallel, wherein a drain supply terminal is provided between the first capacitor and the third capacitor and a source supply terminal is provided between the second capacitor and the third capacitor. The first current source is acted as a forward channel when under simulation and connected between the drain supply terminal and the source supply terminal. The second current source and the body diode are connected in parallel, which are connected with the first current source in parallel. The gate supply terminal, the drain supply terminal and the source supply terminal are connected to a gate terminal, a drain terminal and a source terminal of the target transistor respectively. The system is configured to perform a fitting of a set of I-V values of the target transistor based on the following equation Eq. (1):

$$y = [ {\prod }_{k = 1}^{n} tanh ( {a}_{k} \times {x}_{1} + {b}_{k} ) ] \times F + c$$

y denotes a current through the target transistor, x₁ denotes an applied voltage on the target transistor, aₖ, bₖ and c are circuit-dependent coefficients, F is a function related to the applied voltage.

According to one aspect of the present disclosure, the system is configured to perform a fitting of a set of I-V values of the target transistor based on the following equation Eq. (4):

$${I}_{D S} = \{ \{ [ {\prod }_{k = 1}^{n} tanh ( {G}_{k} \times {V}_{G S} + {H}_{k} ) ] \times J \times {V}_{D S} - K \times {V}_{D S}^{2} \} \times ( 1 + L \times {V}_{G S} ) \} + γ$$

Gₖ, Hₖ, J, K, L and γ are circuit-dependent coefficients, V_{GS} represents a gate-source voltage of the target transistor, V_{DS} represents a drain-source voltage of the target transistor.

According to one aspect of the present disclosure, a method for modeling characteristics of a target transistor is provided. The method uses the following equation Eq. (1) to perform a fitting of a set of I-V values of the transistor:

$$y = [ {\prod }_{k = 1}^{n} tanh ( {a}_{k} \times {x}_{1} + {b}_{k} ) ] \times F + c$$

y denotes a current through the target transistor, x₁ denotes an applied voltage of the target transistor, aₖ, bₖ and c are circuit-dependent coefficients, F is a function related to the applied voltage.

### BRIEF DESCRIPTION OF THE DRAWINGS

The present disclosure will become more fully understood from the detailed description given hereinafter and the accompanying drawings which are given by way of illustration only, and thus are not limitative of the present disclosure, and wherein:

FIG. 1 is an exemplary equivalent circuit for measuring characteristics of a SiC MOS device.

FIGS. 2A to 2C illustrate typical schematic structures of planar DMOS, double-trench UMOS and asymmetric trench UMOS.

FIGS. 3A to 3F are graphs of modelling results and measurement results of the tested devices for first quadrant I-V characteristics under temperatures of 25° C. and 175° C.

FIGS. 4A to 4F are graphs of modelling results and measurement results of the tested devices for first quadrant I-V characteristics under various temperatures from 25° C. to 175° C.

FIGS. 5A to 5F are graphs of modelling results and measurement results of the tested devices for third quadrant I-V characteristics under temperatures of 25° C. and 175° C.

### DETAILED DESCRIPTION OF THE PREFERRED EMBODIMENTS

Prior to turning to the figures, which illustrate exemplary embodiments in detail, it should be understood that this disclosure is not limited to the specific details or methodologies described or shown in the figures. Additionally, the terminology used herein is for descriptive purposes only and should not be considered limiting.

Throughout the specification and claims, the definitions provided below are intended as illustrative examples and are not meant to strictly limit the terms. The terms “a,” “an,” and “the” should be understood to include plural references, unless the context clearly dictates otherwise. The phrases “in an exemplary embodiment,” “in the exemplary embodiment,” and “in exemplary embodiments,” as used herein, do not necessarily refer to the same embodiment or example, although they may in some cases.

The present disclosure is made to accurately model I-V characteristics of a power semiconductor device which acts as a switching device. This switching device may be a MOS (Metal Oxide Semiconductor) or MIS (Metal Insulator Semiconductor) type, such as MOS transistors, particularly wide-bandgap (WBG) semiconductor-based devices like SiC (Silicon Carbide) or GaN (Gallium Nitride). In some examples, the switching device includes, but is not limited to, SiC MOSFETs (Metal-Oxide-Semiconductor Field-Effect Transistors), GaN HEMTs (High Electron Mobility Transistors), SiC JFETs (Junction Gate Field-Effect Transistors), IGBTs (Insulated Gate Bipolar Transistors), and Super Junction MOSFETs. For simplicity, a SiC MOSFET is used as a target device in the exemplary embodiments described in the proceeding sections.

The proposed model uses an equation that allows for the comparatively easy and accurate extraction and approximation of the I-V characteristics, making it applicable to various types and structures of power semiconductor devices.

The approach proposed herein may be applied in the first quadrant (V_{DS}≥0 and V_{GS}≥0) I-V characteristics simulation and the third quadrant (V_{DS}≤0 and V_{GS}≤0) I-V characteristics simulation of the switching device. The proposed modelling involves the following equation Eq. (1):

$$y = \{ [ {\prod }_{k = 1}^{n} tanh ( {a}_{k} \times {x}_{1} + {b}_{k} ) \times F ] \times G + c \} \times H \qquad Eq . ( 1 )$$

It should be understood that the simulation is to evaluate I-V characteristics of the switching device, which can be accurately based on the Eq. (1). Here, y is a current flowing through the target device, namely, the drain current (I_{DS}) or the source current (Is). x₁ is an applied voltage on the target device, which may be V_{DS} or V_{GS}. aₖ, bₖ and c are circuit-dependent coefficients, which may be calculated or estimated based on the target device or by fitting. n is the number of tests. F, G, H are functions related to the applied voltage, V_{DS} or V_{GS}. It should be noted that the coefficients aₖ, bₖ, c and the functions F, G, H can be derived through fitting procedures using the circuit described below. These values depend on the selection and properties of the components in the circuit. In other words, by measuring the I-V characteristics of the target device, the coefficients and functions in the Eq. (1) can be determined. For the sake of brevity, the detailed calculations for deriving these coefficients and functions are not provided here.

In one example, F=ƒ(x₂). In another example, F=ƒ(x₂)×(1+L×x₃). ƒ(x₂) and x₃ may maybe the applied voltages of the target device and L is the short channel length modulation (λ) of the target device, which could be obtained through calculations or measurements.

In one example, the first quadrant I-V characteristics (curves) of the target device is completely calculated and simulated by using the Eq. (1). In another example, the third-quadrant I-V characteristics (curves) of the target device are calculated and modeled using a combined approach based on the Eq. (1) and a standard PN-diode model. In accordance with the exemplary embodiments, the Eq. (1) may be simplified and expressed as follows:

$${I}_{D S} = \{ [ {\prod }_{k = 1}^{n} tanh ( {a}_{k} \times {V}_{G S} + {b}_{k} ) \times {V}_{D S} ] \times f ( {V}_{G S} ) + ( - {d V}_{D S}^{2} ) \} \times ( 1 + L \times {V}_{D S} ) \qquad Eq . ( l - a )$$

$${I}_{S} = \{ [ {\prod }_{k = 1}^{n} tanh ( {a}_{k} \times {V}_{G S} + {b}_{k} ) \times {V}_{D S} ] \times f ( {V}_{G S} ) + ( - {d V}_{D S}^{2} ) \} \qquad Eq . ( l - b )$$

d is a circuit-dependent coefficient and L is the short channel length modulation (λ) of the target device, which could be obtained through calculations or measurements. The Eq. (1-a) may be applied to first quadrant I-V characteristics modelling and the Eq. (1-b) may be applied to third quadrant I-V characteristics modelling.

Similarly, the coefficients aₖ, bₖ, d and the function ƒ(V_{GS}) can be derived through fitting procedures using the circuit described below.

It was found that introducing the tanh function, as shown in the Eq. (1), can more effectively approximate the characteristics of the JFET region in the target device. Additionally, the short channel effects caused by the depletion of the p-well under high V_{DS} may be considered by incorporating the short channel length modulation in the Eq. (1), to better estimate the behavior under the short channel effects. I-V characteristics simulation of the MOS devices can thus be built by using the above Eq. (1).

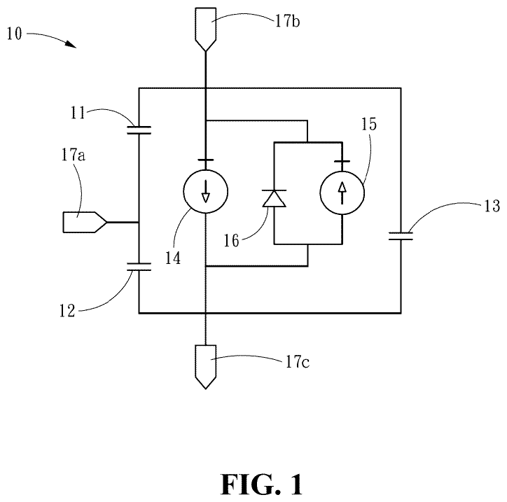

FIG. 1 illustrates an exemplary equivalent circuit for measuring characteristics of the target device. Additional elements or circuits may be included in the circuit 10 shown in FIG. 1. It should be noted that alternative circuits may be configured to employ the model in the present disclosure. The circuit 10 is used to measure the I-V characteristics of the target device for the purpose of constructing an I-V characteristic model based on Eq. (1), by calculating the coefficients and functions in Eq. (1) using the measurement data. In other words, curve fitting based on Eq. (1) may be performed using the measurement data obtained from circuit 10.

The circuit 10 includes a first capacitor 11, a second capacitor 12, a third capacitor 13, a first current source 14, a second current source 15 and a body diode 16. The second capacitor 12 is connected to the first capacitor 11 in series, and a gate supply terminal 17a is provided between the first capacitor 11 and the second capacitor 12 to supply Vgg. The third capacitor 13 is connected to the first capacitor 11 and the second capacitor 12 in parallel, and a drain supply terminal 17b is provided between the first capacitor 11 and the third capacitor 13 to supply Vdd, while a source supply terminal 17c is provided between the second capacitor 12 and the third capacitor 13 to supply Vss. The first current source 14 is connected between the drain supply terminal 17b and the source supply terminal 17c. The second current source 15 is connected with the body diode 16 in parallel, the combination of the second current source 15 and the body diode 16 is further connected with the first current source 14 in parallel. The gate supply terminal 17a, the drain supply terminal 17b and the source supply terminal 17c in the circuit 10 are connected to a gate terminal, a drain terminal and a source terminal of the SiC MOS device (the target device) under measurement, respectively. The first current source 14 is acted as a forward channel and the second current source 15 is acted as a floating channel when under simulation.

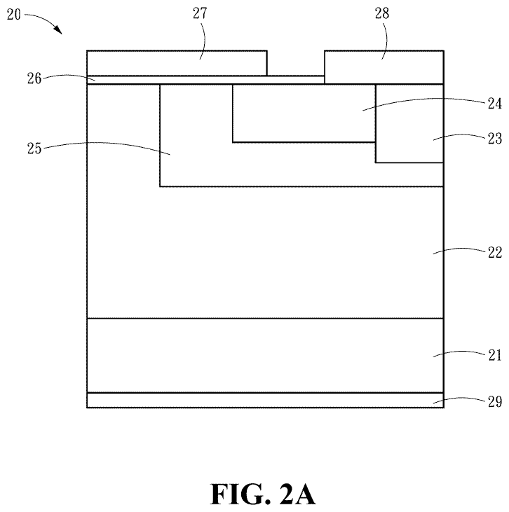

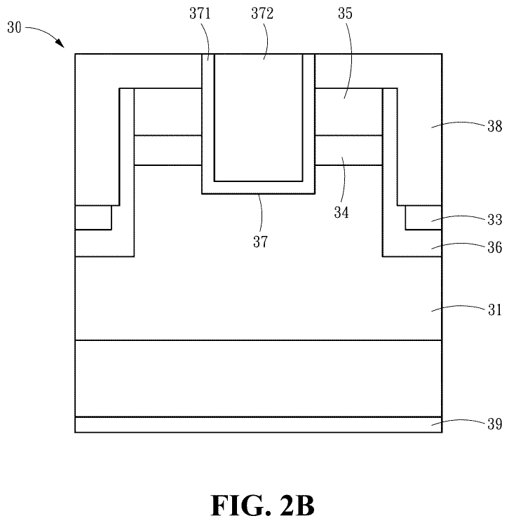

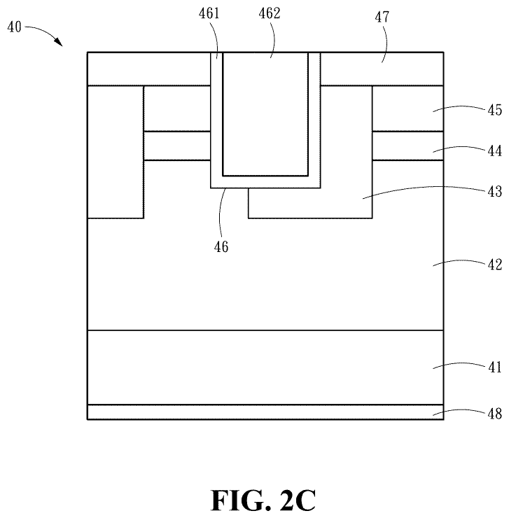

In the examples herein, the SiC MOS device may be one of planar DMOS, double-trench UMOS or asymmetric trench UMOS. The typical schematic structures of these MOS (Metal Oxide Semiconductor) devices are shown in FIGS. 2A to 2B.

FIG. 2A illustrates an example of the planar DMOS 20, comprising an N-type substrate 21, an N-type drift layer 22, a P+ region 23, an N+ region 24, a P-well region 25, an insultation layer 26, a gate electrode 27, a source electrode 28 and a drain electrode 29.

FIG. 2B illustrates an example of the double-trench UMOS 30, comprising an N-type substrate 31, an N-type drift layer 32, a P+ region 33, a P-type body region 34, an N+ region 35, a P-well region 36, a trench 37, an insultation layer 371, a gate electrode 372, a source electrode 38 and a drain electrode 39.

FIG. 2C illustrates an example of the asymmetric trench UMOS 40, comprising an N-type substrate 41, an N-type drift layer 42, a P+ region 43, a P-type body region 44, an N+ region 45, a trench 46, an insultation layer 461, a gate electrode 462, a source electrode 47 and a drain electrode 48.

In one exemplary embodiment, the Eq. (1) may be expressed as follows:

$${I}_{D} = {I}_{p k 0} ( 1 + tanh φ ) tanh ( {αV}_{D S} ) ( 1 + {λ V}_{D S} )$$

α may be expressed as follows:

$$\begin{matrix}α = {α}_{r} ( 1 + tanh φ ) {α}_{s} \\ φ = {\sum }_{0 \leq n \leq 3} {{P}_{n} ( {V}_{G S} - {V}_{p k s} )}^{n} \\ p = {p}_{1}^{′} ( 1 + {B}_{1} / {cosh}^{2} ( {B}_{2} {V}_{D S} ) )\end{matrix}$$

The above equations offer an approach to modeling the target device more effectively in conventional SPICE (Simulation Program with Integrated Circuit Emphasis) model, balancing the need for accuracy with computational efficiency function can be employed for the JFET region. While this approach may neglect some of the physical properties inherent in more detailed models, it provides a more effective means of approximating the characteristics of the JFET region.

To demonstrate the results of the proposed approach, simulations on the first quadrant I_{DS}−V_{DS} characteristics using the above equations are conducted on several commercially available SiC MOSFET devices, as listed in the following Table 1. The tested devices 1 and 2 are the SiC DMOS devices, the tested devices 3 and 4 are the SiC UMOS devices, and the tested devices 5 and 6 are the SiC SBD-embedded MOS devices.

TABLE 1

| No. | Manufacturer | Model |
|---|---|---|
| Tested device 1 | Wolfspeed | C3M0032120D |
| Tested device 2 | Infineon | NVH4L040N120M3S |
| Tested device 3 | Infineon | IMW120R045M1 |
| Tested device 4 | ROHM | SCT3030KL |
| Tested device 5 | ROHM | SCT4018KE |
| Tested device 6 | Toshiba | TW045N120C |

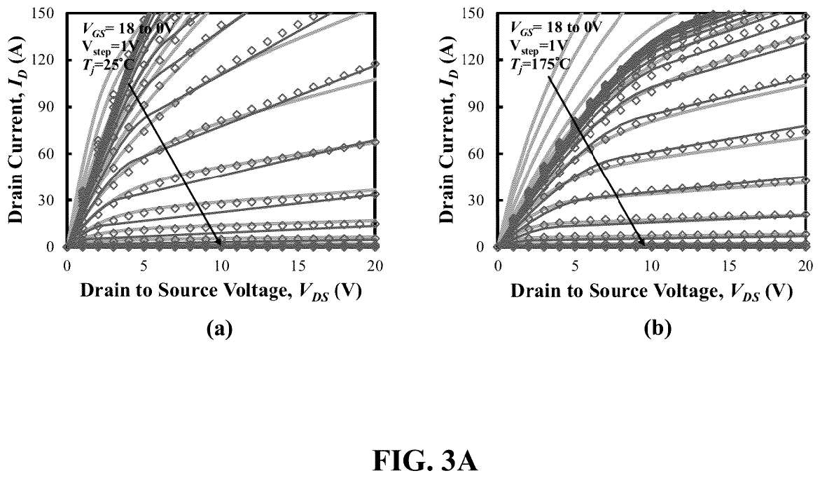

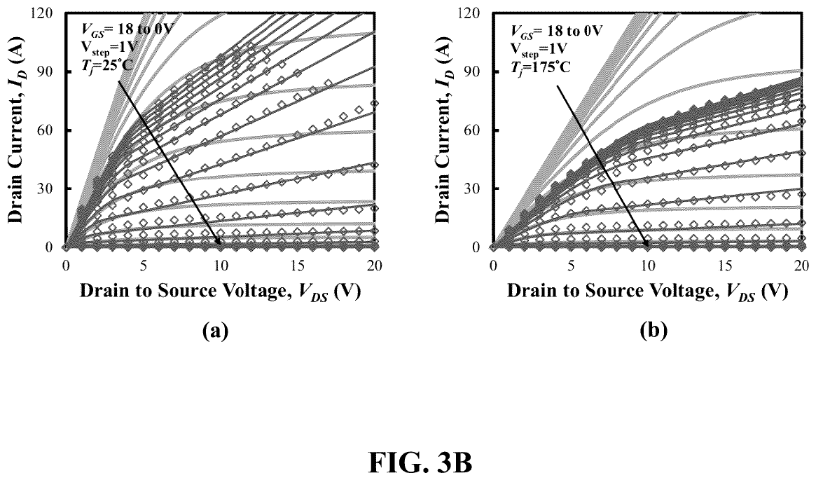

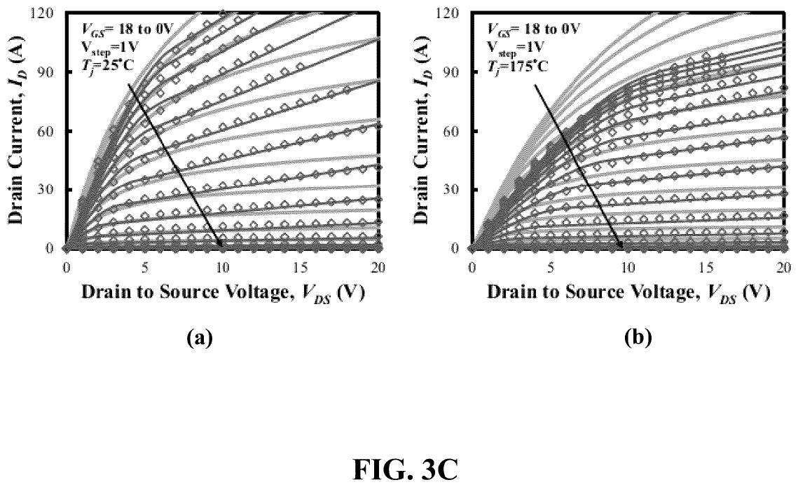

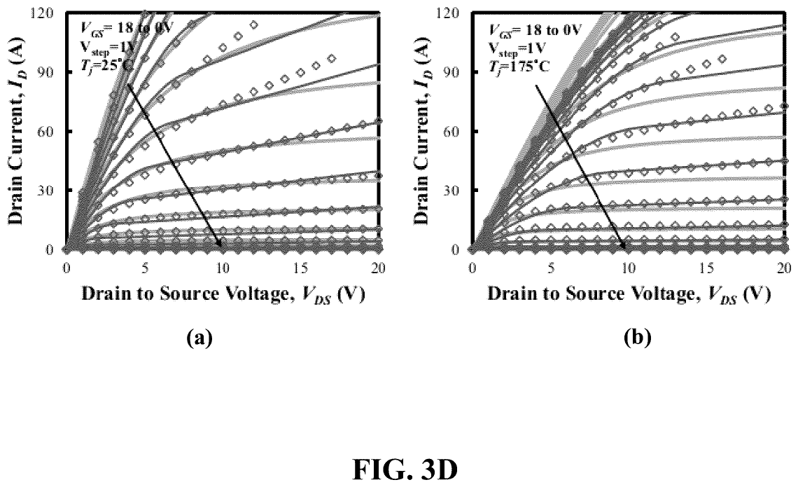

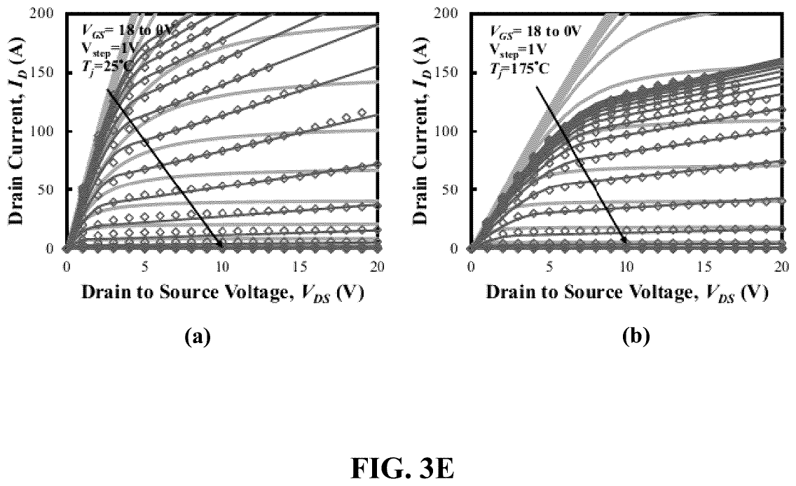

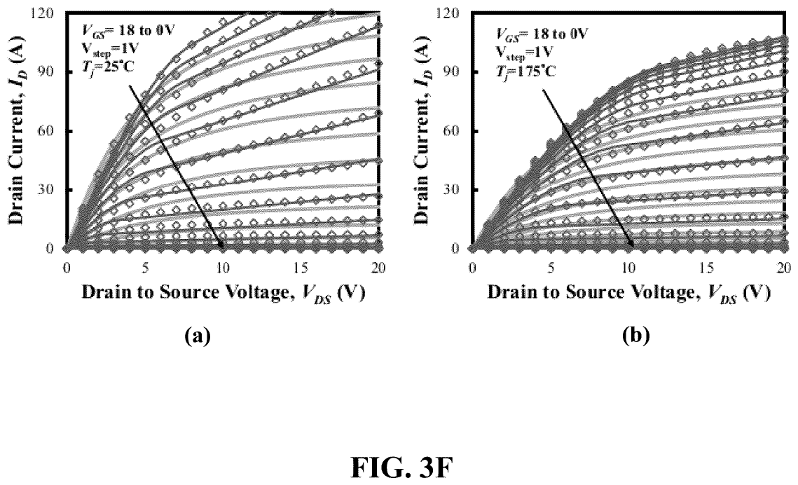

The results are shown in FIGS. 3A to 3F, the square symbol represents the measurement data, the light grey line is the modelling results obtained by using the manufacturer's model (SPICE model) and the dark grey is the modelling results obtained by the proposed approach. Each dataset represents a different V_{GS} value, ranging from 18V to 0V (incrementing by 1V between each adjacent dataset from left to right). All of the tests are conducted under temperatures of 25° C. and 175° C., to evaluate the behaviour at the elevated operating temperature.

FIG. 3A (a) and (b) show the first quadrant I_{DS}−V_{DS} characteristics of the tested device 1 at 25° C. and 175° C., respectively. FIG. 3B (a) and (b) show the first quadrant I_{DS}−V_{DS} characteristics of the tested device 2 at 25° C. and 175° C., respectively. FIG. 3C (a) and (b) show the first quadrant I_{DS}−V_{DS} characteristics of the tested device 3 at 25° C. and 175° C., respectively. FIG. 3D (a) and (b) show the first quadrant I_{DS}−V_{DS} characteristics of the tested device 4 at 25° C. and 175° C., respectively. FIG. 3E (a) and (b) show the first quadrant I_{DS}−V_{DS} characteristics of the tested device 5 at 25° C. and 175° C., respectively. FIG. 3F (a) and (b) show the first quadrant I_{DS}−V_{DS} characteristics of the tested device 6 at 25° C. and 175° C., respectively. From the comparison, it is obvious that the proposed approach is much closer to the actual measurement than the manufacturer's model, which means that the proposed approach is more accurate to model the I-V characteristics of the target device.

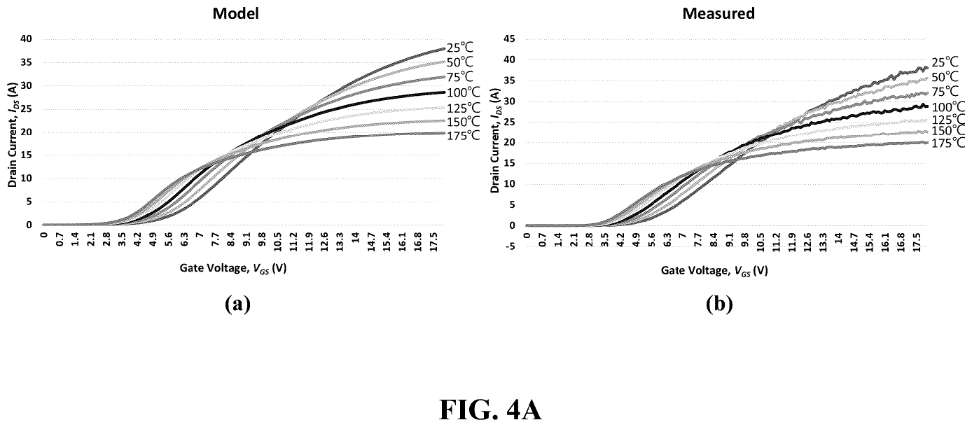

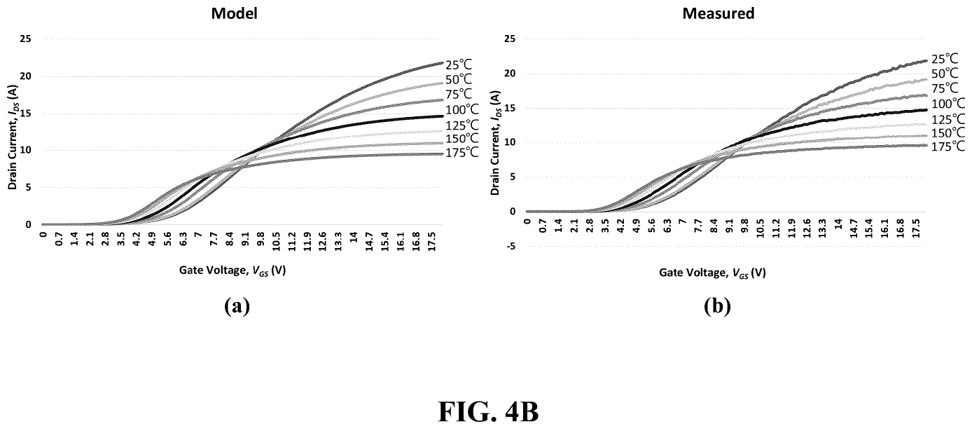

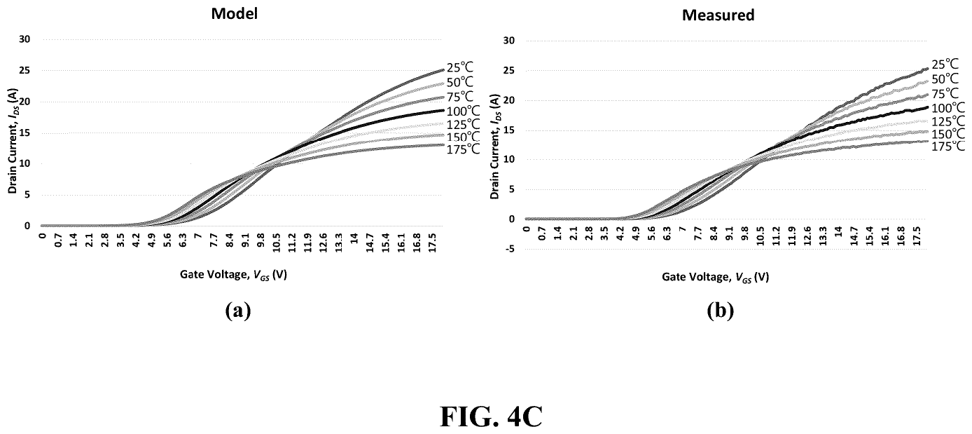

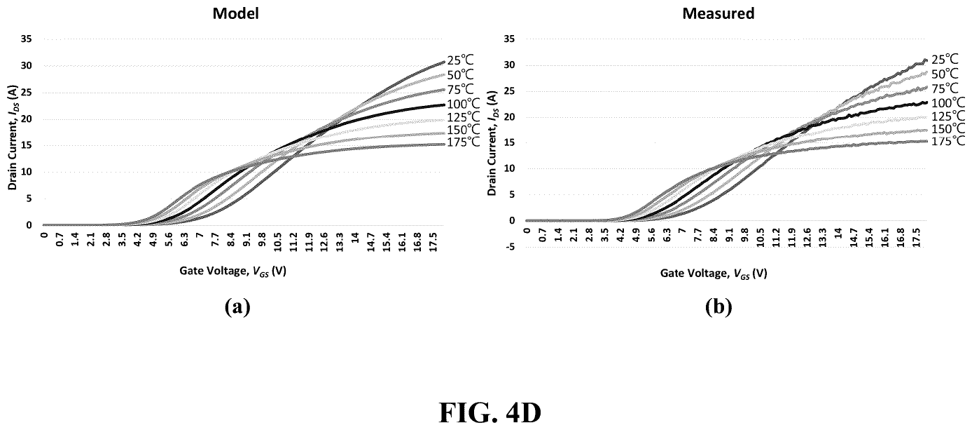

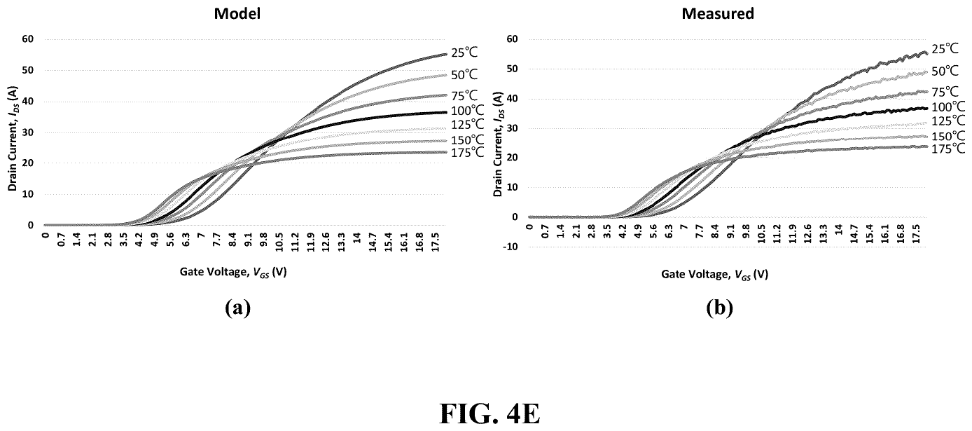

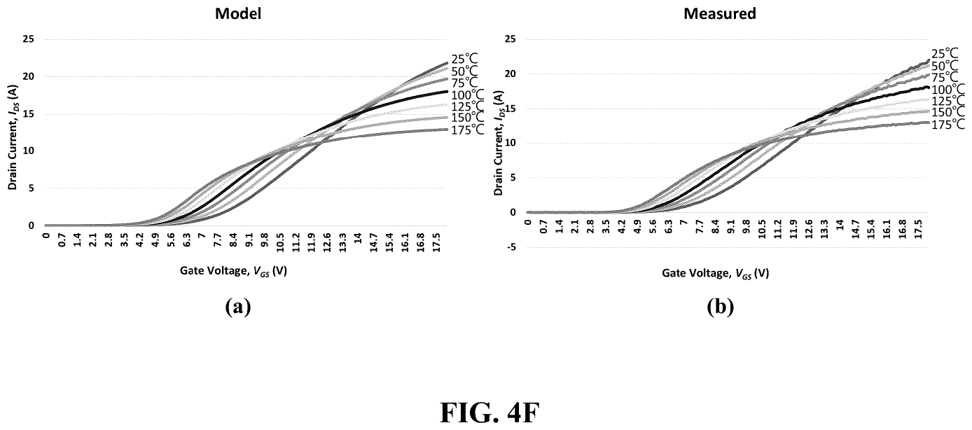

To compare the results under various temperatures, I_{DS}−V_{GS} characteristics modellings are performed at 25° C., 50° C., 75° C., 100° C., 125° C., 150° C. and 175° C. on tested devices 1 to 6, the results are shown in FIGS. 4A to 4F. FIG. 4A (a) and (b) show the simulated (by using the Eq. (1)) and measured I_{DS}−V_{DS} characteristics of the tested device 1, respectively. FIG. 4B (a) and (b) show the simulated (by using the Eq. (1)) and measured I_{DS}−V_{DS} characteristics of the tested device 2, respectively. FIG. 4C (a) and (b) show the simulated (by using the Eq. (1)) and measured I_{DS}−V_{DS} characteristics of the tested device 3, respectively. FIG. 4D (a) and (b) show the simulated (by using the Eq. (1)) and measured I_{DS}−V_{DS} characteristics of the tested device 4, respectively. FIG. 4E (a) and (b) show the simulated (by using the Eq. (1)) and measured I_{DS}−V_{DS} characteristics of the tested device 5, respectively. FIG. 4F (a) and (b) show the simulated (by using the Eq. (1)) and measured I_{DS}−V_{DS} characteristics of the tested device 6, respectively. The results show a high consistency between the modelling result and the measurement, proving that the proposed approach is able to accurately simulate I-V behavior of SiC MOSFET device from room temperature to operating temperature.

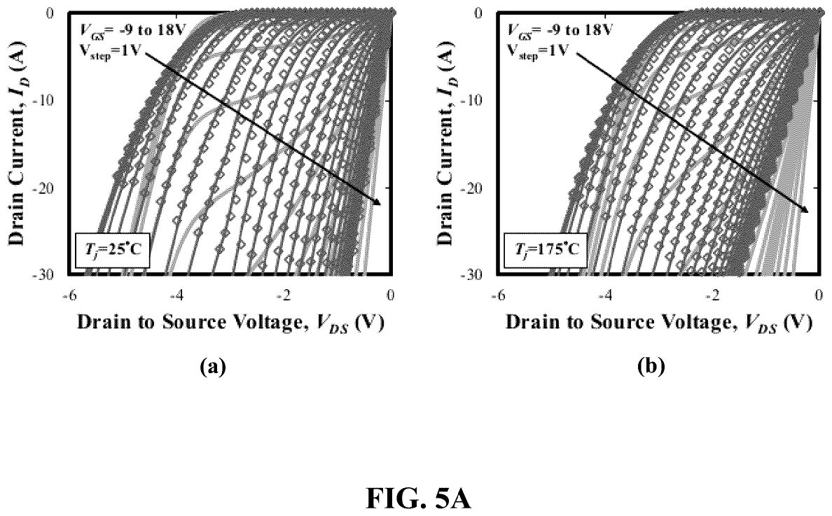

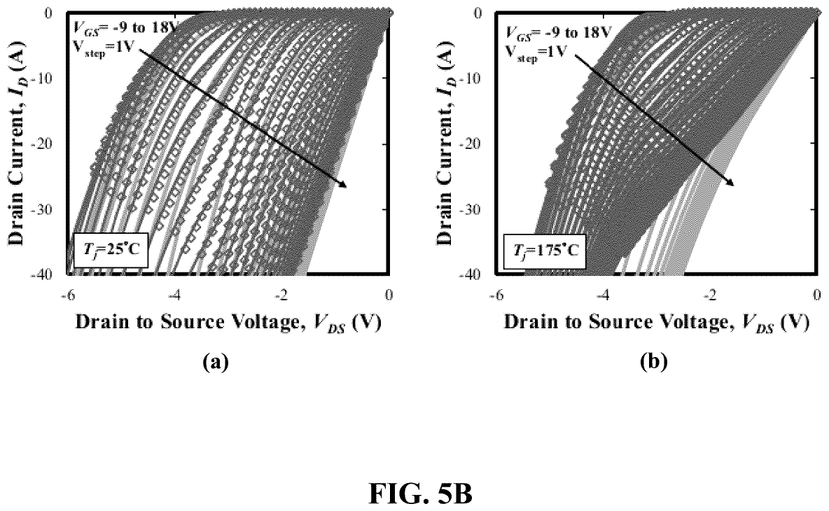

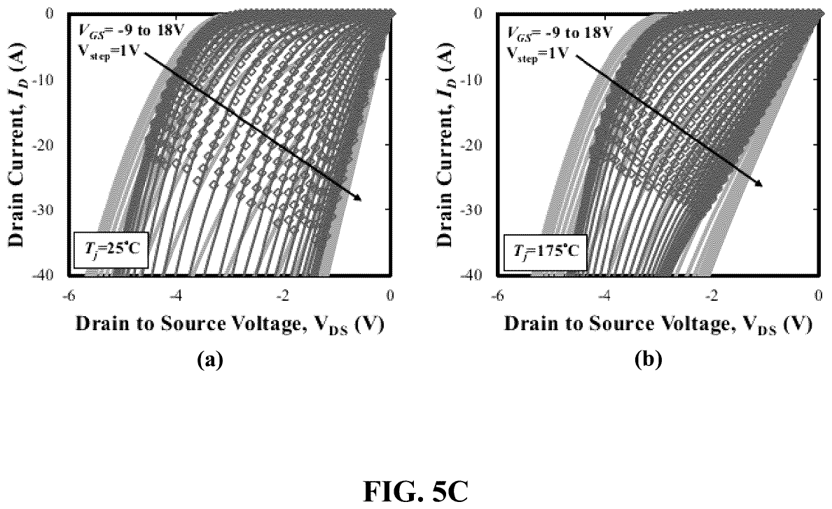

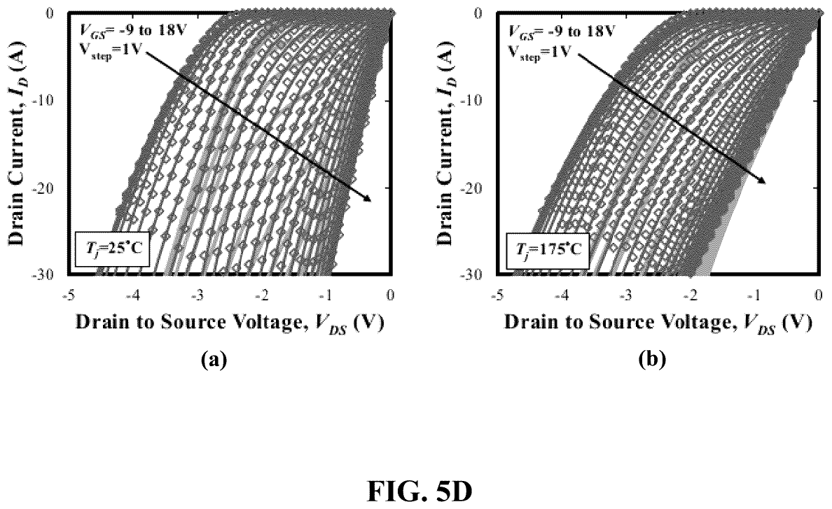

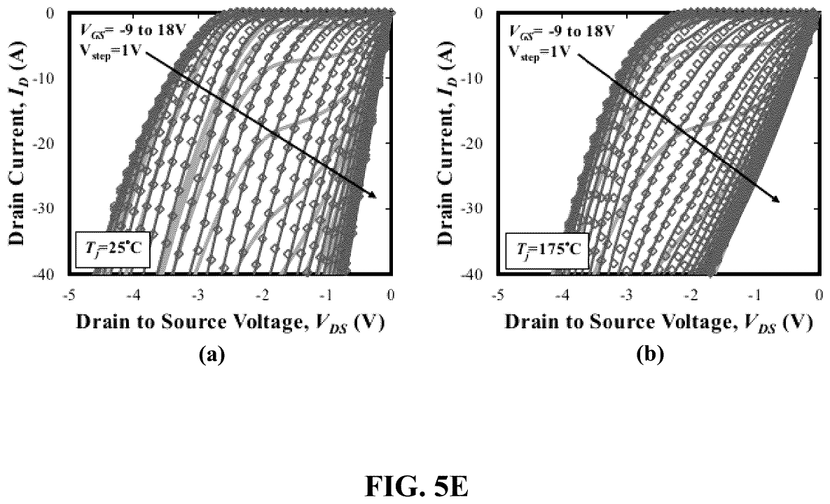

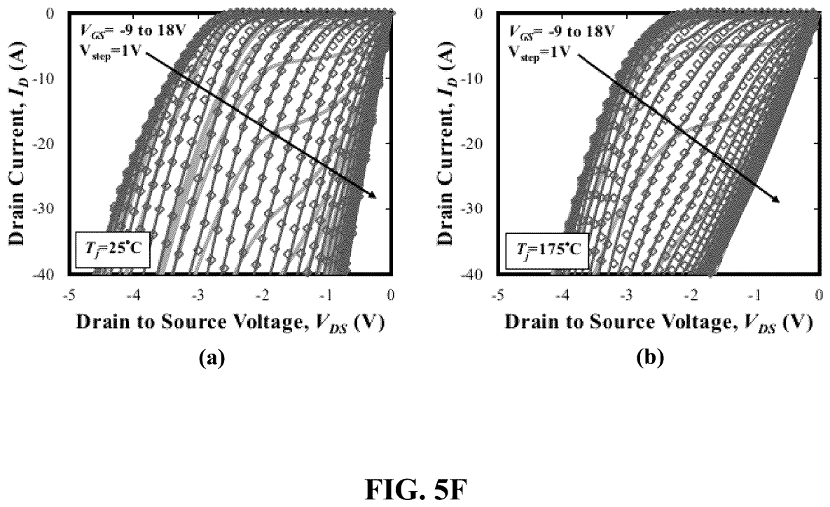

In addition to the first quadrant I-V characteristics as described above, the third quadrant I_{DS}−V_{DS} characteristics are also modelled by using the invention and measured. The results are shown in FIGS. 5A to 5F, the square symbol represents the measurement data, the light grey line is the modelling results obtained by using the manufacturer's model and the dark grey is the modelling results obtained by a combined approach composed of the Eq. (1) and a PN-diode model. Each dataset represents a different V_{GS} value, ranging from −9V to 18V (incrementing by 1V between each adjacent dataset from left to right). All of the tests are conducted under temperatures of 25° C. and 175° C., to evaluate the behaviour at the elevated operating temperature.

FIG. 5A (a) and (b) show the third quadrant I_{DS}−V_{DS} characteristics of the tested device 1 at 25° C. and 175° C., respectively. FIG. 5B (a) and (b) show the third quadrant I_{DS}−V_{DS} characteristics of the tested device 2 at 25° C. and 175° C., respectively. FIG. 5C (a) and (b) show the third quadrant I_{DS}−V_{DS} characteristics of the tested device 3 at 25° C. and 175° C., respectively. FIG. 5D (a) and (b) show the third quadrant I_{DS}−V_{DS} characteristics of the tested device 4 at 25° C. and 175° C., respectively. FIG. 5E (a) and (b) show the third quadrant I_{DS}−V_{DS} characteristics of the tested device 5 at 25° C. and 175° C., respectively. FIG. 5F (a) and (b) show the third quadrant I_{DS}−V_{DS} characteristics of the tested device 6 at 25° C. and 175° C., respectively.

Each tested device is measured and simulated based on both the conventional SPICE model and the proposed models under various junction temperatures and V_{GS} values. To provide a comprehensive analysis of the temperature dependency and the model performance, this disclosure selects seven different temperature values from 25° C. to 175° C. for each device, thereby mitigating the potential for “cherry-picking” favorable results.

Additionally, the modelling proposed in the present disclosure is practically applicable across various SiC MOSFET structures, thereby enhancing the effectiveness and reducing the cost.

What is claimed is:

1. A system for modeling characteristics of a transistor, comprising:
a circuit, including:
a first capacitor;
a second capacitor, connected to the first capacitor in series, wherein a gate supply terminal is provided between the first capacitor and the second capacitor;
a third capacitor, connected to the first capacitor and the second capacitor in parallel, wherein a drain supply terminal is provided between the first capacitor and the third capacitor and a source supply terminal is provided between the second capacitor and the third capacitor;
a first current source acted as a forward channel when under simulation, connected between the drain supply terminal and the source supply terminal; and
a second current source and a body diode connected in parallel, which are connected with the first current source in parallel;
wherein the gate supply terminal, the drain supply terminal and the source supply terminal are connected to a gate terminal, a drain terminal and a source terminal of a transistor respectively;
wherein the system is configured to perform a fitting of a set of I-V values of the transistor based on the following equation Eq. (1):
$$y = [ {\prod }_{k = 1}^{n} tanh ( {a}_{k} \times {x}_{1} + {b}_{k} ) ] \times F + c$$
wherein y denotes a current through the transistor, x₁ denotes an applied voltage on the transistor, aₖ, bₖ and c are circuit-dependent coefficients, F is a function related to the applied voltage.

2. The system of claim 1, wherein F is represented by the following equation Eq. (2):
$$F = f ( {x}_{2} ) .$$

3. The system of claim 1, wherein F is represented by the following equation Eq. (3):
$$F = f ( {x}_{2} ) \times ( 1 + L \times {x}_{3} ) .$$

4. The system of claim 1, wherein the transistor is a SiC mosfet.

5. The system of claim 1, wherein the transistor is SiC DMOS or SiC UMOS.

6. A system for modeling characteristics of a transistor, comprising:
a circuit, including:
a first capacitor;
a second capacitor, connected to the first capacitor in series, wherein a gate supply terminal is provided between the first capacitor and the second capacitor;
a third capacitor, connected to the first capacitor and the second capacitor in parallel, wherein a drain supply terminal is provided between the first capacitor and the third capacitor and a source supply terminal is provided between the second capacitor and the third capacitor;
a first current source, connected between the drain supply terminal and the source supply terminal; and
a second current source and a body diode connected in parallel, which are connected with the first current source in parallel;
wherein the gate supply terminal, the drain supply terminal and the source supply terminal are connected to a gate terminal, a drain terminal and a source terminal of a transistor respectively;
wherein the system is configured to perform a fitting of a set of I-V values of the transistor based on the following equation Eq. (4):
$${I}_{D S} = \{ \{ [ {\prod }_{k = 1}^{n} tanh ( {G}_{k} \times {V}_{G S} + {H}_{k} ) ] \times J \times {V}_{D S} - K \times {V}_{D S}^{2} \} \times ( 1 + L \times {V}_{G S} ) \} + γ$$
wherein Gₖ, Hₖ, J, K, L and γ are circuit-dependent coefficients, V_{GS} represents a gate-source voltage of the transistor, V_{DS} represents a drain-source voltage of the transistor.

7. The system of claim 6, wherein the applied voltage in the Eq. (4) is dependent on a quadrant of operation of the transistor.

8. The system of claim 6, wherein the transistor is a SiC mosfet.

9. The system of claim 6, wherein the transistor is SiC DMOS or SiC UMOS.

10. A method for modeling characteristics of a transistor, wherein the method uses the following equation Eq. (1) to perform a fitting of a set of I-V values of the transistor:
$$y = [ {\prod }_{k = 1}^{n} tanh ( {a}_{k} \times {x}_{1} + {b}_{k} ) ] \times F + c$$
wherein y denotes a current through the transistor, x₁ denotes an applied voltage of the transistor, aₖ, bₖ and c are circuit-dependent coefficients, F is a function related to the applied voltage.

11. The method of claim 10, wherein F is represented by the following equation Eq. (2):
$$F = f ( {x}_{2} ) .$$

12. The method of claim 10, wherein F is represented by the following equation Eq. (3):
$$F = f ( {x}_{2} ) \times ( 1 + L \times {x}_{3} ) .$$

13. The method of claim 10, wherein the transistor is a SiC mosfet.

14. The method of claim 10, wherein the transistor is one of SiC DMOS or SiC UMOS.
